(19) United States
(12) Patent Application Publication
(10) Pub. No.: US 2025/0174601 A1
(43) Pub. Date: May 29, 2025

(54) SEMICONDUCTOR PACKAGE INCLUDING A PLURALITY OF CHIPS STACKED IN A VERTICAL DIRECTION

(71) Applicant: Samsung Electronics Co., Ltd., Suwon-si (KR)

(72) Inventors: Dongki CHOI, Suwon-si (KR); Dongjoo CHOI, Suwon-si (KR)

(73) Assignee: Samsung Electronics Co., Ltd., Suwon-si (KR)

(21) Appl. No.: 18/956,583

(22) Filed: Nov. 22, 2024

(30) Foreign Application Priority Data
Nov. 24, 2023 (KR) 10-2023-0165901

(51) Int. Cl. H01L 25/065; H01L 23/00; H01L 23/31

(52) U.S. Cl. CPC H01L 25/0657; H01L 24/16; H01L 24/32; H01L 24/73; H01L 23/3107; H01L 2224/16146; H01L 2224/16227; H01L 2224/32145; H01L 2224/32225; H01L 2224/73204; H01L 2225/06513; H01L 2225/06541; H01L 2225/06555

(57) ABSTRACT

A semiconductor package includes a first substrate; a base chip on the first substrate; a plurality of first semiconductor chips stacked, in a first direction, on the base chip; a second semiconductor chip stacked, in the first direction, on an uppermost first semiconductor chip among the plurality of first semiconductor chips; a plurality of third semiconductor chips stacked, in the first direction, on the second semiconductor chip; and a fourth semiconductor chip stacked, in the first direction, on an uppermost third semiconductor chip among the plurality of third semiconductor chips, wherein a footprint of the second semiconductor chip is greater than a footprint of each of the first semiconductor chips and each of the third semiconductor chips, and a footprint of the base chip is greater than a footprint of the second semiconductor chip.

### CROSS-REFERENCE TO RELATED APPLICATION

This application is based on and claims priority to Korean Patent Application No. 10-2023-0165901, filed on Nov. 24, 2023, in the Korean Intellectual Property Office, the disclosure of which is incorporated by reference herein in its entirety.

### BACKGROUND

### 1. Field

The embodiments of the present disclosure relate to a semiconductor package, and more particularly, to a semiconductor package including a plurality of semiconductor chips stacked in a vertical direction.

### 2. Description of Related Art

Recently, the demand for a portable device has been rapidly increasing in the electronic products market, and thus, miniaturization and weight reduction of electronic components mounted on these electronic products are continuously required. In order to reduce the size and weight of electronic components, the semiconductor package mounted on the electronic components is required to process high-capacity data while its volume decreases and to minimize defects.

In one or more examples, semiconductor packages that stack multiple semiconductor chips in a vertical direction are being developed to reduce the size of semiconductor packages. In this case, research on semiconductor packages that maintain structural reliability even if the number of semiconductor chips to be stacked increases continues. However, as the size of the stack increases, there is a problem with warpage and non-conductive film (NCF) control of a chip in the semiconductor package.

### SUMMARY

The Embodiments of the present disclosure provide a semiconductor package with improved reliability.

Furthermore, the embodiments of the present disclosure are not limited to the tasks described above, and other tasks may be clearly understood by one of ordinary skill in the art from the following description.

The embodiments of the present disclosure provide a semiconductor package as follows.

According to one or more embodiments, a semiconductor package comprising: a first substrate; a base chip on the first substrate; a plurality of first semiconductor chips stacked, in a first direction, on the base chip; a second semiconductor chip stacked, in the first direction, on an uppermost first semiconductor chip among the plurality of first semiconductor chips; a plurality of third semiconductor chips stacked, in a first direction, on the second semiconductor chip; and a fourth semiconductor chip stacked, in a first direction, on an uppermost third semiconductor chip among the plurality of third semiconductor chips, wherein a footprint of the second semiconductor chip is greater than a footprint of each of the first semiconductor chips and each of the third semiconductor chips, and wherein a footprint of the base chip is greater than a footprint of the second semiconductor chip.

According to one or more embodiments, a semiconductor package comprising: a first substrate; a base chip on the first substrate; a plurality of first semiconductor chips stacked, in a first direction, on the base chip; a second semiconductor chip stacked, in the first direction, on an uppermost first semiconductor chip among the plurality of first semiconductor chips; a plurality of third semiconductor chips stacked, in the first direction, on the second semiconductor chip; a fourth semiconductor chip stacked, in the first direction, on an uppermost third semiconductor chip among the plurality of third semiconductor chips; a plurality of fifth semiconductor chips stacked, in the first direction, on the fourth semiconductor chip; and a sixth semiconductor chip stacked, in the first direction, on an uppermost fifth semiconductor chip among the plurality of fifth semiconductor chips, wherein a footprint of each of the second semiconductor chip and the fourth semiconductor chip is greater than a footprint of each of the first semiconductor chips, each of the third semiconductor chips, and each of the fifth semiconductor chips, and a footprint of the base chip is greater than a footprint of each of the second semiconductor chips and the fourth semiconductor chip.

According to one or more embodiments, a semiconductor package comprising: a first substrate; a base chip on the first substrate; a plurality of first semiconductor chips stacked, in a first direction, on the base chip and having a footprint smaller than a footprint of the base chip; a second semiconductor chip stacked, in the first direction, on an uppermost first semiconductor chip among the plurality of first semiconductor chips and having a footprint larger than a footprint of each of the first semiconductor chips; a plurality of third semiconductor chips stacked, in the first direction, on the second semiconductor chip and having a footprint smaller than the footprint of the second semiconductor chip; and a fourth semiconductor chip stacked, in the first direction, on an uppermost third semiconductor chip among the plurality of third semiconductor chips, wherein the number of the first semiconductor chips is eight, the number of the third semiconductor chips is two, a first adhesive layer is arranged between each first semiconductor chip adjacent to each other among the first semiconductor chips, a second adhesive layer is between an uppermost first semiconductor chip among the first semiconductor chips and the second semiconductor chip, a footprint of the second adhesive layer is greater than a footprint of the first adhesive layer, and a distance between a side surface of the first semiconductor chip in a second direction perpendicular to the first direction and a side surface of the second semiconductor chip in the second direction is in a range of about 50 μm to about 100 μm.

### BRIEF DESCRIPTION OF DRAWINGS

Embodiments of the present disclosure will be more clearly understood from the following detailed description taken in conjunction with the accompanying drawings in which:

FIG. 1 is a cross-sectional view schematically illustrating a semiconductor package according to embodiments;

FIG. 2 is a cross-sectional view schematically illustrating a semiconductor package according to embodiments;

FIG. 3 is a cross-sectional view schematically illustrating a semiconductor package according to embodiments;

FIG. 4 is a cross-sectional view schematically illustrating a semiconductor package according to embodiments;

FIG. 5 is a cross-sectional view schematically illustrating a semiconductor package according to embodiments; and

FIGS. 6 to 14 are cross-sectional views schematically illustrating a semiconductor package according to embodiments.

### DETAILED DESCRIPTION OF EMBODIMENTS

Hereinafter, embodiments of the present disclosure will be described in detail with reference to the accompanying drawings. The same reference numerals are used for the same components in the drawings, and redundant descriptions thereof will be omitted.

Hereinafter, example embodiments will be described with reference to the accompanying drawings. Hereinafter, terms, such as ‘top,’ ‘upper portion,’ ‘upper surface,’ ‘bottom,’ ‘lower portion,’ ‘lower surface,’ and ‘side surface’ may be understood as illustrated in the drawings, except for cases indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

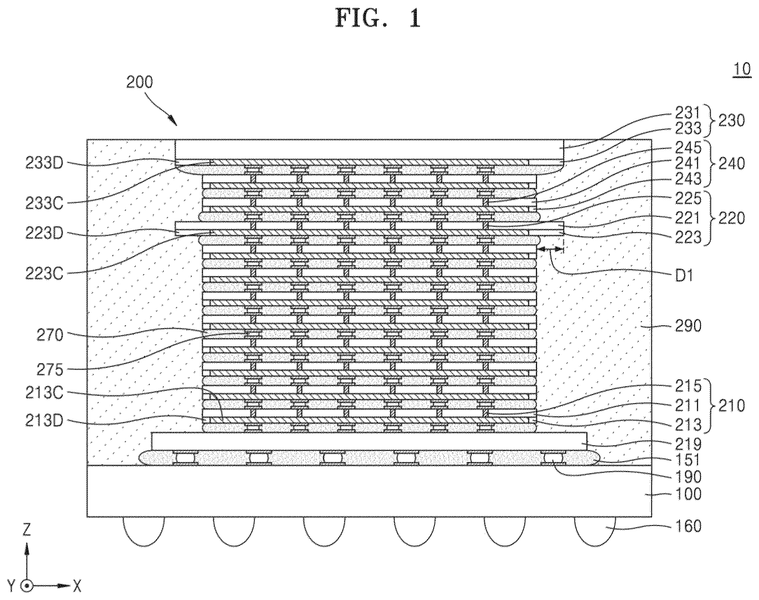

FIG. 1 is a cross-sectional view schematically illustrating a semiconductor package according to embodiments.

Referring to FIG. 1, a semiconductor package 10 may include a first substrate 100, an external connection terminal 160, a chip stack structure 200, and a first molding member 290.

The first substrate 100 is a substrate on which the chip stack structure 200 is mounted, and may be located below the chip stack structure 200. Specifically, the first substrate 100 may be positioned between the chip stack structure 200 and the external connection terminal 160. The first substrate 100 may be electrically connected to both the chip stack structure 200 and the external connection terminal 160.

According to embodiments, at least one of an upper surface and a lower surface of the first substrate 100 may have a flat shape. In the drawings, an X-axis direction and a Y-axis direction indicate a direction parallel to a flat surface of a top surface or a bottom surface of the first substrate 100, and the X-axis direction and the Y-axis direction may be perpendicular to each other. The Z-axis direction may indicate a direction perpendicular to a top surface or a bottom surface of the first substrate 100. In one or more examples, the Z-axis direction may be a direction perpendicular to the X-Y plane.

In one or more examples, in the following drawings, a first horizontal direction, a second horizontal direction, and a vertical direction may be understood as follows. The first horizontal direction may be understood as an X-axis direction, the second horizontal direction may be understood as a Y-axis direction, and the vertical direction may be understood as a Z-axis direction. In one or more examples, the Z-axis direction may be a first direction, the X-axis direction may be a second direction perpendicular to the first direction, and the Y-axis direction may be a third direction perpendicular to the first direction and the second direction.

The first substrate 100 may include an insulating layer and a wiring formed in the insulating layer. According to embodiments, the first substrate 100 may include a redistribution structure formed through a redistribution process. In this case, the wiring of the first substrate 100 may be understood as a redistribution pattern, and the insulating layer of the first substrate 100 may be understood as a redistribution insulating layer. In one or more examples, the wiring of the first substrate 100 may be a metal or an alloy of metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like, but is not limited thereto, and in some embodiments, the wiring may be formed by stacking a metal or an alloy of metals on a seed layer including copper, titanium, titanium nitride, or titanium tungsten. In one or more examples, the insulating layer of the first substrate 100 may include a photo imageable dielectric (PID) or photosensitive polyimide (PSPI).

However, the embodiments are not limited thereto, and in some embodiments, the first substrate 100 may be formed based on a ceramic substrate, a printed circuit board (PCB), an organic substrate, or any other suitable material known to one of ordinary skill in the art. In this case, the wiring of the first substrate 100 may include copper, nickel, stainless steel, or beryllium copper, and the insulating layer of the first substrate 100 may include at least one material selected from Frame Retardant 4 (FR-4), Tetrafunctional epoxy, polyphenylene ether, epoxy/polyphenylene oxide, bismaleimide triazine (BT), Thermount, Cyanate ester, polyimide, and Liquid Crystal polymer.

In one or more examples, the external connection terminal 160 is arranged on a bottom surface of the first substrate 100 and may be electrically connected to the first substrate 100 through a pad formed on the bottom surface of the first substrate 100. Specifically, the external connection terminal 160 may be electrically connected to wirings formed in the first substrate 100 through a substrate pad attached to the bottom surface of the first substrate 100. Since the external connection terminal 160 is located under the first substrate 100, the top surface of the external connection terminal 160 may be in physical contact with the substrate pad attached to the bottom surface of the first substrate 100. The external connection terminal 160 may be electrically connected to an external device, for example, a motherboard, a PCB, a package substrate, etc. Since the external connection terminal 160 is arranged between the external device and the first substrate 100, the bottom surface of the external connection terminal 160 may be physically connected to the external device.

In one or more examples, the external connection terminal 160 may be formed of solder balls. However, depending on embodiments, the external connection terminal 160 may have a structure including a pillar and solder. The external connection terminal 160 may include at least one of copper (Cu), silver (Ag), gold (Au), and tin (Sb).

The chip stack structure 200 may be arranged on a top surface of the first substrate 100. According to embodiments, the chip stack structure 200 may be mounted on the top surface of the first substrate 100 in a flip chip manner through a first bump 190. A flip chip method is a connection method for connecting integrated circuit chips to packages or other components by placing the chips on its backside and bonding the chip directly to another surface (e.g., substrate) rather than relying on wire bonds between circuit chips to packages or other components. The first bump 190 may be arranged between the chip stack structure 200 and the first substrate 100. The first bump 190 may include a pillar structure, a ball structure, or a solder layer.

According to embodiments, an under-fill material layer 151 surrounding the first bump 190 may be arranged between the chip stack structure 200 and the first substrate 100. The under-fill material layer 151 may include, for example, epoxy resin formed in a capillary under-fill method. However, in some embodiments, a first molding member 290 may be directly filled into a gap between the chip stack structure 200 and the first substrate 100 through a molded under-fill process. In this case, the under-fill material layer 151 may be omitted.

In one or more examples, the chip stack structure 200 may include a base chip 219, a first semiconductor chip 210, a second semiconductor chip 220, and a top layer semiconductor chip 230. The base chip 219 is a chip located lowermost in the chip stack structure 200 and may be directly connected to the first substrate 100 through the first bump 190. According to embodiments, the base chip 219 may integrate signals of the first semiconductor chip 210, the second semiconductor chip 220, and the top layer semiconductor chip 230 stacked above the base chip 219 to transmit the integrated signals to the outside, and transmit signals and power from the outside to the first semiconductor chip 210, the second semiconductor chip 220, and the top layer semiconductor chip 230. Accordingly, the base chip 219 may be referred to as a buffer chip or a control chip in this disclosure.

In one or more examples, the base chip 219 may include various types of individual devices. The individual devices may include various microelectronics devices, metal-oxide-semiconductor field effect transistors (MOSFET), such as a complementary metal-oxide-semiconductor (CMOS) transistor, system large scale integration (LSI), image sensors such as CMOS imaging sensor (CIS), micro-electro-mechanical system (MEMS), active devices, and passive devices. In some embodiments, the base chip 219 may not include a memory cell. For example, semiconductor devices included in the base chip 219 may include test logic circuits such as serial-parallel conversion circuits, design for tests (DFT), Joint Test Action Group (JTAG), memory built-in self-test (MBIST), and signal interface circuits such as physical layers (PHY).

The first semiconductor chip 210 may be stacked on the base chip 219 in the vertical direction Z. According to embodiments, a plurality of first semiconductor chips 210 may be provided. The plurality of first semiconductor chips 210 may be defined as chips located under the second semiconductor chip 220 and stacked on the base chip 219 in the vertical direction Z among a plurality of chips included in the chip stack structure 200. For example, the plurality of first semiconductor chips 210 may be chips located between the base chip 219 and the second semiconductor chip 220 among the plurality of chips included in the chip stack structure 200. For example, as shown in FIG. 1, a total of eight first semiconductor chips 210 may be provided from the first semiconductor chip 210 located right above the base chip 219 to the first semiconductor chip 210 located right below the second semiconductor chip 220. However, the number of first semiconductor chips 210 is not limited thereto, and one or more first semiconductor chips 210 may be provided. Each of the first semiconductor chips 210 may be referred to as a memory chip or a core chip.

According to embodiments, the first semiconductor chip 210 may include a first semiconductor substrate 211, a first through electrode 215, and a first semiconductor device layer 213. The first semiconductor substrate 211 may have bottom and top surfaces opposite to each other. The bottom surface of the first semiconductor substrate 211 may face the first substrate 100. The bottom surface may be referred to as an active surface, and a top surface opposite to the bottom surface may be referred to as an inactive surface.

The first semiconductor substrate 211 may include silicon (Si), for example, crystalline silicon, polycrystalline silicon, or amorphous silicon. In another embodiment, the first semiconductor substrate 211 may include a semiconductor element, such as germanium (Ge), or a compound semiconductor, such as silicon carbide (SiC), gallium arsenide (GaAs), indium arsenide (InAs), and indium phosphate (InP). In one or more examples, the first semiconductor substrate 211 may have a silicon on insulator (SOI) structure. For example, the first semiconductor substrate 211 may include a buried oxide (BOX) layer. The first semiconductor substrate 211 may include a conductive region, for example, an impurity-doped well or an impurity-doped structure. In one or more examples, the first semiconductor substrate 211 may have various device isolation structures such as a shallow trench isolation (STI) structure.

According to embodiments, the first semiconductor device layer 213 may be formed on the bottom surface, which is the active surface, of the first semiconductor substrate 211. The first semiconductor device layer 213 may include a first core region 213C and a first dummy region 213D. Individual devices may be formed in the first core region 213C of the first semiconductor device layer 213. The individual devices may include various microelectronics devices, MOSFETs, such as a CMOS transistors, system large scale integration (LSI), image sensors such as CIS, MEMS, active elements, and passive elements. The first dummy region 213D of the first semiconductor device layer 213 may include silicon. Individual devices may not be formed in the first dummy region 213D of the first semiconductor device layer 213. The first dummy region 213D may be substantially the same as or similar to a scribe lane region formed on a wafer.

In one or more examples, the first through electrode 215 may be formed to penetrate the first semiconductor substrate 211 in a vertical direction. In some embodiments, the first through electrode 215 may be formed to penetrate a portion of the first semiconductor device layer 213 and the first semiconductor substrate 211. The first through electrode 215 may extend in the vertical direction Z from the first semiconductor device layer 213 toward a top surface of the first semiconductor substrate 211 and may be electrically connected to wirings provided in the first semiconductor device layer 213. The first through electrode 215 may have a tapered shape in which a horizontal width of the first through electrode 215 decreases or increases as a level according to a vertical direction increases. At least a portion of the first through electrode 215 may have a columnar shape. The first through electrode 215 may be a through silicon via (TSV).

In one or more examples, the plurality of first semiconductor chips 210 may be stacked in a row in the vertical direction Z. For example, side surfaces of the plurality of first semiconductor chips 210 may be positioned on the same plane. However, the embodiments are not limited thereto, and the plurality of first semiconductor chips 210 may be offset-stacked according to one direction. In one or more examples, the sides surfaces of the plurality of first semiconductor chips 210 may be surfaces of the first semiconductor chips 210 extending in the Z direction.

In some embodiments, the plurality of first semiconductor chips 210 stacked in the vertical direction Z may be stacked through a second bump 275 and an adhesive layer 270. For example, the first semiconductor chip 210 located lowermost among the plurality of first semiconductor chips 210 may be stacked on the base chip 219 through the second bump 275 in a flip chip manner. In one or more examples, the first semiconductor chip 210 stacked on the top surface of any one of the first semiconductor chips 210 may also be stacked in a flip chip manner through the second bump 275. In one or more examples, the second bump 275 may include, for example, a micro-bump. According to embodiments, the second bump 275 may include a pillar structure, a ball structure, or a solder layer. In one or more examples, an adhesive layer 270 may be arranged between the base chip 219 and the lowermost first semiconductor chip 210, between the first semiconductor chips 210 closest to each other in the vertical direction Z, and between the uppermost first semiconductor chip 210 and the second semiconductor chip 220. In some embodiments, the adhesive layer 270 may be a film having its own adhesive properties. For example, the adhesive layer 270 may include a die attach film (DAF) or a non-conductive film (NCF).

According to embodiments, the length of the first semiconductor chip 210 in the first horizontal direction X may be less than the length of the base chip 219 in the first horizontal direction X. A footprint of the first semiconductor chip 210 may be less than a footprint of the base chip 219. In one or more examples, a footprint of a chip may be an area of a substrate covered by the chip. For example, with respect to the drawings, the foot print of the first semiconductor chip 210 may be determined by the length of the first semiconductor chip 210 in the X direction multiplied by the length of the first semiconductor chip 210 in the Y direction. According to embodiments, a thickness of the first semiconductor chip 210 in the vertical direction Z may be in a range of about 30 μm to about 45 μm. However, the thickness of the first semiconductor chip 210 in the vertical direction Z is not limited thereto.

According to embodiments, the first semiconductor chip 210 may include a memory chip. The memory chip may be, for example, a volatile memory chip, such as dynamic random access memory (DRAM) or static random access memory (SRAM), or may be a nonvolatile memory chip, such as phase-change random access memory (PRAM), magnetoresistive random access memory (MRAM), ferroelectric random access memory (FeRAM), or resistive random access memory (RRAM). However, the embodiments are not limited thereto, and the first semiconductor chip 210 may be, for example, a logic chip, such as a central processing unit (CPU), a graphics processing unit (GPU), a microprocessor such as or an application processor (AP), an analog device, or a digital signal processor.

The second semiconductor chip 220 may be located on a top surface of the first semiconductor chip 210 located uppermost among the plurality of first semiconductor chips 210. According to embodiments, a footprint of the second semiconductor chip 220 may be greater than a footprint of the first semiconductor chip 210. In some embodiments, a side surface of the second semiconductor chip 220 may be arranged to protrude further in the horizontal directions X and Y than a side surface of the first semiconductor chip 210. The entire top surface of the first semiconductor chip 210 may overlap the second semiconductor chip 220 in the vertical direction Z.

According to embodiments, a distance D1 between a side surface of the second semiconductor chip 220 in the first horizontal direction X and a side surface of the first semiconductor chip 210 in the first horizontal direction X may range from about 50 μm to about 100 μm. According to embodiments, the side surfaces of the second semiconductor chip 220 in the horizontal directions X and Y may be located inside the side surfaces of the base chip 219 in the horizontal directions X and Y.

In some embodiments, the second semiconductor chip 220 may be stacked on the first semiconductor chip 210 through the second bump 275 and the adhesive layer 270. The second semiconductor chip 220 may be stacked on the first semiconductor chip 210 in a flip chip manner through the second bump 275. An adhesive layer 270 may be arranged between the first semiconductor chip 210 located uppermost among the plurality of first semiconductor chips 210 and the second semiconductor chip 220. According to embodiments, the adhesive layer 270 located between the uppermost first semiconductor chip 210 and the second semiconductor chip 220 may further protrude in the horizontal directions X and Y than the adhesive layer 270 located between the first semiconductor chips 210. In the present disclosure, the adhesive layer 270 positioned between the first semiconductor chips 210 may be defined as a first adhesive layer, and the adhesive layer 270 positioned between the first semiconductor chip 210 and the second semiconductor chip 220 may be defined as a second adhesive layer. In this case, a footprint of the second adhesive layer may be greater than a footprint of the first adhesive layer.

In one or more examples, the second semiconductor chip 220 may include a second semiconductor substrate 221, a second semiconductor device layer 223, and a second through electrode 225. The second semiconductor substrate 221 may have bottom and top surfaces opposite to each other. The bottom surface may face the first semiconductor chip 210. The bottom surface may be referred to as an active surface, and the top surface opposite to the bottom surface may be referred to as an inactive surface. According to embodiments, the second semiconductor substrate 221 may include silicon (Si), for example, crystalline silicon, polycrystalline silicon, or amorphous silicon. The second semiconductor substrate 221 may have a length in the horizontal directions X and Y that is greater than the first semiconductor substrate 211. The second semiconductor device layer 223 may be formed on a bottom surface, which is an active surface, of the second semiconductor substrate 221. The second semiconductor device layer 223 may include a second core region 223C and a second dummy region 223D. According to embodiments, individual devices may be formed in the second core region 223C. According to embodiments, the second dummy region 223D may include silicon. Individual devices may not be formed in the second dummy region 223D. The second dummy region 223D may be substantially the same as or similar to a scribe lane region formed on a wafer.

According to embodiments, a footprint of the second core region 223C may be substantially the same as a footprint of the first core region 213C. Lengths of the second core region 223C in the horizontal directions X and Y may be substantially the same as lengths of the first core region 213C in the horizontal directions X and Y. A footprint of the second dummy region 223D may be greater than a footprint of the first dummy region 213D. Lengths of the second dummy region 223D in the horizontal directions X and Y may be greater than lengths of the first dummy region 213D in the horizontal directions X and Y.

In one or more examples, the second through electrode 225 may be formed to penetrate the second semiconductor substrate 221 in a vertical direction. In some embodiments, the second through electrode 225 may be formed to penetrate a portion of the second semiconductor device layer 223 and the second semiconductor substrate 221. The second through electrode 225 may extend in the vertical direction Z from the second semiconductor device layer 223 toward a top surface of the first semiconductor substrate 211 and may be electrically connected to wirings provided in the second semiconductor device layer 223. The second through electrode 225 may have a tapered shape in which a horizontal width decreases or increases as a level according to a vertical direction increases. At least a portion of the second through electrode 225 may have a columnar shape. The second through electrode 225 may be a TSV.

In one or more examples, a third semiconductor chip 240 may be stacked on the second semiconductor chip 220 in the vertical direction Z. According to embodiments, a plurality of third semiconductor chips 240 may be provided. The plurality of third semiconductor chips 240 may be defined as chips located under the top layer semiconductor chip 230 and stacked on the second semiconductor chip 220 in the vertical direction Z among the plurality of chips included in the chip stack structure 200. For example, the plurality of third semiconductor chips 240 may be understood as chips located between the second semiconductor chip 220 and the top layer semiconductor chip 230 among the plurality of chips included in the chip stack structure 200. For example, as shown in FIG. 1, a total of two thirds of the semiconductor chips 240 may be provided, from the third semiconductor chip 240 located just above the second semiconductor chip 220 to the second semiconductor chip 220 located just below the top layer semiconductor chip 230. However, the number of second semiconductor chips 220 is not limited thereto, and one or three or more second semiconductor chips 220 may be provided. Each of the third semiconductor chips 240 may be referred to as a memory chip or a core chip.

In some embodiments, the plurality of third semiconductor chips 240 stacked in the vertical direction Z may be stacked through a second bump 275 and an adhesive layer 270. For example, the third semiconductor chip 240 located lowermost among the plurality of third semiconductor chips 240 may be stacked on the second semiconductor chip 220 in a flip chip manner through the second bump 275. In one or more examples, two adjacent third semiconductor chips 240 in the vertical direction Z may also be stacked in the vertical direction Z through the second bump 275 and the adhesive layer 270. A second bump 275 and an adhesive layer 270 may be arranged between the third semiconductor chip 240 positioned uppermost among the plurality of third semiconductor chips 240 and the top layer semiconductor chip 230.

In one or more examples, the third semiconductor chip 240 may include a third semiconductor substrate 241, a third semiconductor device layer 243, and a third through electrode 245. Since the internal configuration of the third semiconductor chip 240 is substantially the same as or similar to the internal configuration of the first semiconductor chip 210, a detailed description thereof is omitted.

In one or more examples, the top layer semiconductor chip 230 may be stacked in the vertical direction Z on the third semiconductor chip 240 positioned uppermost among the plurality of third semiconductor chips 240. The top layer semiconductor chip 230 may include a top layer semiconductor substrate 231 and a top layer semiconductor device layer 233. According to embodiments, the top layer semiconductor chip 230 may not include a through electrode.

According to embodiments, a thickness of the top layer semiconductor chip 230 in the vertical direction Z may be greater than the thicknesses of each of the first to third semiconductor chips 210, 220, and 240. In some embodiments, a thickness of the top layer semiconductor chip 230 in the vertical direction Z may range from about 140 μm to about 180 μm. However, the thickness of the top layer semiconductor chip 230 in the vertical direction Z is not limited to the above range. According to embodiments, a footprint of the top layer semiconductor chip 230 may be greater than a footprint of the third semiconductor chip 240. In some embodiments, a footprint of the top layer semiconductor chip 230 may have substantially the same size as a footprint of the second semiconductor chip 220.

The top layer semiconductor chip 230 may be stacked on the top surface of the third semiconductor chip 240 through the second bump 275 and the adhesive layer 270. The second bump 275 and the adhesive layer 270 may be arranged between the third semiconductor chip 240 stacked uppermost among a plurality of third semiconductor chips 240 and the top layer semiconductor chip 230. The adhesive layer 270 arranged between the uppermost third semiconductor chip 240 among the plurality of third semiconductor chips 240 and the top layer semiconductor chip 230 may further protrude in the horizontal directions X and Y than the adhesive layer 270 positioned between the third semiconductor chips 240.

According to embodiments, among the plurality of adhesive layers 270 formed in the chip stack structure 200, both the adhesive layer 270 between the first semiconductor chip 210 and the second semiconductor chip 220, and the adhesive layer 270 between the third semiconductor chip 240 and the top layer semiconductor chip 230 may protrude further in the horizontal directions X and Y than the adhesive layers 270 between the first semiconductor chips 210.

In one or more examples, the first molding member 290 may be formed on a top surface of the first substrate 100 to surround the chip stack structure 200. The first molding member 290 may include a molding material such as an epoxy molding compound (EMC) or a photosensitive material such as a photoimageable encapsulant (PIE). In some embodiments, a portion of the first molding member 290 may include an insulating material such as a silicon oxide layer, a silicon nitride layer, or a silicon oxynitride layer. However, the embodiments are not limited thereto, and the first molding member 290 may include thermosetting resin such as epoxy resin, thermoplastic resin such as polyimide, or resin including a reinforcing material such as an inorganic filler, specifically Ajinomoto Build-up Film (ABF), FR-4, BT, etc.

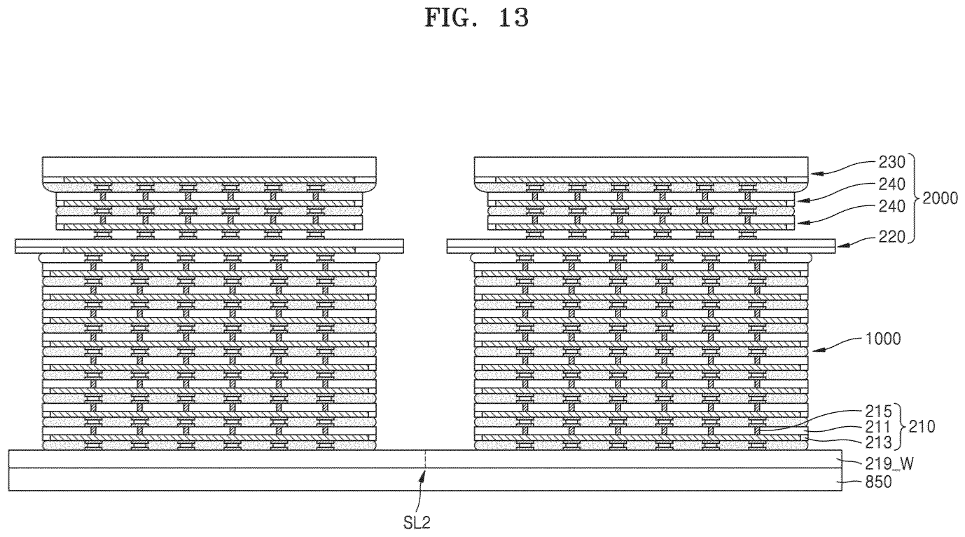

The semiconductor package 10 according to the embodiments of the present disclosure may be formed by forming a first structure 1000 (FIG. 13) including a base chip 219 and a first semiconductor chip 210 and a second structure 2000 (FIG. 13) including a second semiconductor chip 220, a third semiconductor chip 240, and a top layer semiconductor chip 230 to stack the second structure 2000 on the first structure 1000. Since the first structure 1000 and the second structure 2000 are formed separately, warpage that may occur while the number of semiconductor chips to be stacked increases may be prevented.

In one or more examples, when the second structure 2000 is stacked on the first structure 1000, the adhesive layer 270 arranged between the first structure 1000 and the second structure 2000 may ascend from a bottom surface of the second semiconductor chip 220 along a side surface of the second semiconductor chip 220. However, in the semiconductor package 10 according to the embodiments of the present disclosure, since the footprint of the second semiconductor chip 220 located at the lowest level in the second structure 2000 is greater than the footprint of the first semiconductor chip 210 of the first structure 1000, the adhesive layer 270 may increase a path extending along the bottom surface of the second semiconductor chip 220 to prevent or minimize the adhesive layer 270 from rising along the side surface of the second semiconductor chip 220. In one or more examples, since the second dummy region 223D of the second semiconductor chip 220 is larger than the first dummy region 213D of the first semiconductor chip 210, a portion occupied by silicon in the chip stack structure 200 may be larger. Accordingly, the thermal expansion coefficient inside the chip stack structure 200 may become more uniform, thereby reducing warpage of semiconductor chips.

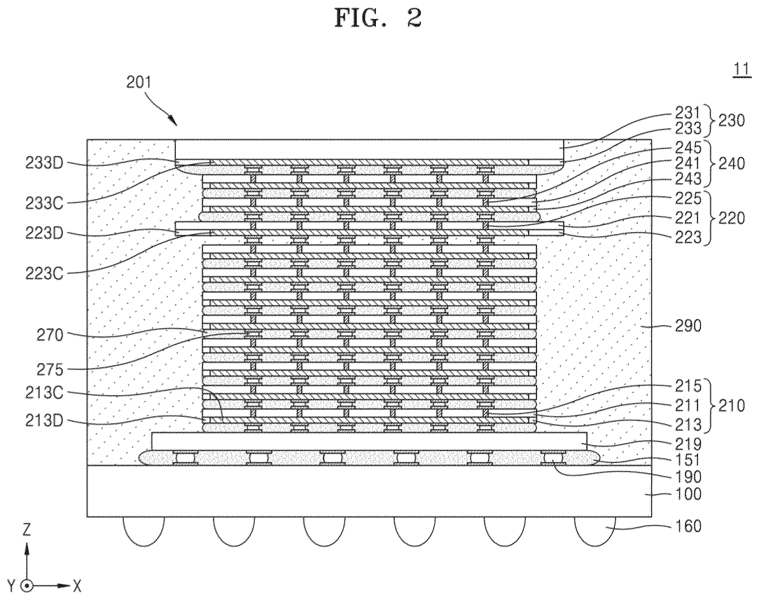

FIG. 2 is a cross-sectional view schematically illustrating a semiconductor package according to embodiments. Hereinafter, redundant descriptions between the semiconductor package 10 described with reference to FIG. 1 and a semiconductor package 11 to be described with reference to FIG. 2 are omitted and differences therebetween are mainly described.

Referring to FIG. 2, according to one or more embodiments, the semiconductor package 11 may include a first substrate 100, an external connection terminal 160, a chip stack structure 201, and a first molding member 290. The chip stack structure 201 may be mounted on a top surface of the first substrate 100 in a flip chip manner. The chip stack structure 201 may include a base chip 219, a first semiconductor chip 210, a second semiconductor chip 220, a third semiconductor chip 240, and a top layer semiconductor chip 230. The base chip 219 is a chip located lowermost in the chip stack structure 201, and may be directly connected to the first substrate 100 through a first bump 190. The first semiconductor chip 210 may be stacked on the base chip 219 in the vertical direction Z. According to embodiments, a plurality of first semiconductor chips 210 may be provided. The plurality of first semiconductor chips 210 may be defined as chips located under the second semiconductor chip 220 and stacked on the base chip 219 in the vertical direction Z among a plurality of chips included in the chip stack structure 201. For example, the plurality of first semiconductor chips 210 may be understood as chips located between the base chip 219 and the second semiconductor chip 220 among the plurality of chips included in the chip stack structure 201. An adhesive layer 270 may be arranged between the base chip 219 and the lowermost first semiconductor chip 210, between the first semiconductor chips 210 closest to each other in the vertical direction Z, and between the uppermost first semiconductor chip 210 and the second semiconductor chip 220. In some embodiments, the adhesive layer 270 may be a film having its own adhesive properties. For example, the adhesive layer 270 may include a DAF or an NCF.

According to embodiments, the second semiconductor chip 220 may be mounted on the first semiconductor chip 210 located uppermost among the plurality of first semiconductor chips 210. The second semiconductor chip 220 may be mounted on the first semiconductor chip 210 through a reflow process. In this case, an adhesive layer 270 may not be arranged between the second semiconductor chip 220 and the first semiconductor chip 210. Therefore, the second bump 275 and the first molding member 290 surrounding the second bump 275 may be arranged between the second semiconductor chip 220 and the first semiconductor chip 210.

A third semiconductor chip 240 may be stacked on the second semiconductor chip 220 in the vertical direction Z. According to embodiments, a plurality of third semiconductor chips 240 may be provided. The plurality of third semiconductor chips 240 may be defined as chips located under the top layer semiconductor chip 230 and stacked on the second semiconductor chip 220 in the vertical direction Z among the plurality of chips included in the chip stack structure 201. The top layer semiconductor chip 230 may be stacked in the vertical direction Z on the uppermost third semiconductor chip 240 positioned among the plurality of third semiconductor chips 240. The top layer semiconductor chip 230 may include a top layer semiconductor substrate 231 and a top layer semiconductor device layer 233. According to embodiments, the top layer semiconductor chip 230 may not include a through electrode.

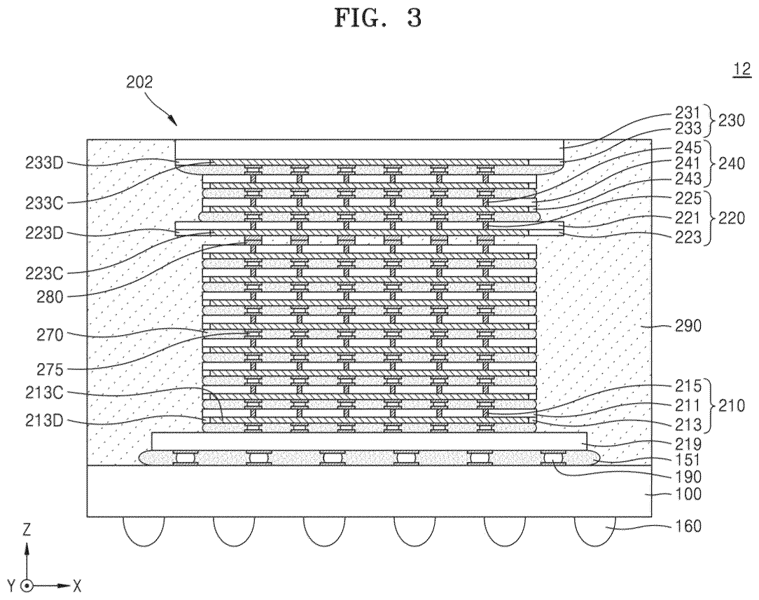

FIG. 3 is a cross-sectional view schematically illustrating a semiconductor package according to embodiments. Hereinafter, redundant descriptions between the semiconductor package 11 described with reference to FIG. 2 and a semiconductor package 12 to be described with reference to FIG. 3 are omitted and differences therebetween are mainly described.

Referring to FIG. 3, the semiconductor package 12 may include a first substrate 100, an external connection terminal 160, a chip stack structure 202, and a first molding member 290. The chip stack structure 202 may be mounted on a top surface of the first substrate 100 in a flip chip manner. The chip stack structure 202 may include a base chip 219, a first semiconductor chip 210, a second semiconductor chip 220, a third semiconductor chip 240, and a top layer semiconductor chip 230. The base chip 219 is a chip located lowermost in the chip stack structure 202, and may be directly connected to the first substrate 100 through a first bump 190. The first semiconductor chip 210 may be stacked on the base chip 219 in the vertical direction Z. According to embodiments, a plurality of first semiconductor chips 210 may be provided. The plurality of first semiconductor chips 210 may be defined as chips located under the second semiconductor chip 220 and stacked on the base chip 219 in the vertical direction Z among a plurality of chips included in the chip stack structure 202. That is, the plurality of first semiconductor chips 210 may be understood as chips located between the base chip 219 and the second semiconductor chip 220 among the plurality of chips included in the chip stack structure 202.

An adhesive layer 270 may be arranged between the base chip 219 and the lowermost first semiconductor chip 210, between the first semiconductor chips 210 closest to each other in the vertical direction Z, and between the uppermost first semiconductor chip 210 and the second semiconductor chip 220. In some embodiments, the adhesive layer 270 may be a film having its own adhesive properties. For example, the adhesive layer 270 may include a DAF or an NCF.

According to embodiments, the second semiconductor chip 220 may be mounted on the first semiconductor chip 210 located uppermost among the plurality of first semiconductor chips 210. The second semiconductor chip 220 may be connected to the first semiconductor chip 210 through direct bonding. The direct bonding may include dielectric-to-dielectric bonding, copper-to-copper bonding, and hybrid bonding in which the dielectric-dielectric bonding and the metal-metal bonding occur together. The direct bonding may be diffusion bonding in which two interfaces including the same material and facing each other are arranged to face each other, and metal atoms or dielectric materials in contact with each other are integrated through diffusion by contacting each other and applying heat to the interfaces. Therefore, the second semiconductor chip 220 may be connected by direct bonding through a chip pad 280 arranged on a bottom surface of the second semiconductor chip 220 and a chip pad 280 arranged on a top surface of the first semiconductor chip 210 located uppermost among the plurality of the first semiconductor chips 210. According to embodiments, the chip pad 280 may include copper. Since the second semiconductor chip 220 is mounted on the first semiconductor chip 210 through direct bonding, the adhesive layer 270 and the second bump 275 may not be arranged between the second semiconductor chip 220 and the first semiconductor chip 210. The chip pad 280 and the first molding member 290 may be arranged between the second semiconductor chip 220 and the first semiconductor chip 210.

A third semiconductor chip 240 may be stacked on the second semiconductor chip 220 in the vertical direction Z. According to embodiments, a plurality of third semiconductor chips 240 may be provided. The plurality of third semiconductor chips 240 may be defined as chips located under the top layer semiconductor chip 230 and stacked on the second semiconductor chip 220 in the vertical direction Z among the plurality of chips included in the chip stack structure 202. The top layer semiconductor chip 230 may be stacked in the vertical direction Z on the third semiconductor chip 240 positioned uppermost among the plurality of third semiconductor chips 240. The top layer semiconductor chip 230 may include a top layer semiconductor substrate 231 and a top layer semiconductor device layer 233. According to embodiments, the top layer semiconductor chip 230 may not include a through electrode.

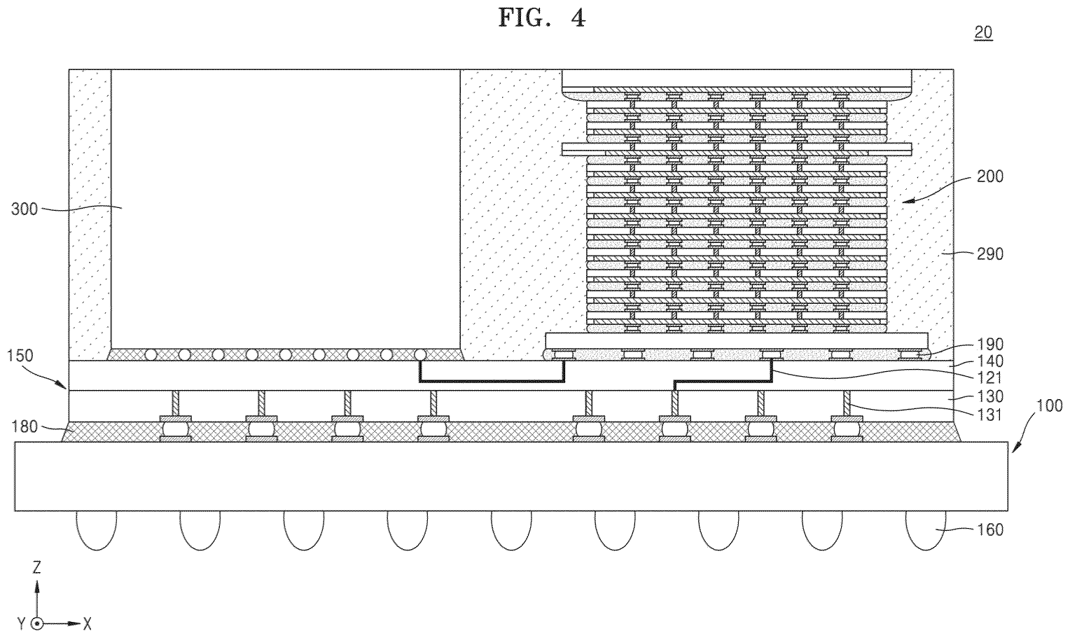

FIG. 4 is a cross-sectional view schematically illustrating a semiconductor package according to embodiments. Hereinafter, redundant descriptions between the semiconductor package 10 described with reference to FIG. 1 and a semiconductor package 20 to be described with reference to FIG. 4 are omitted and differences therebetween are mainly described.

Referring to FIG. 4, the semiconductor package 20 may include a first substrate 100, an interposer substrate 150, a chip stack structure 200, and a semiconductor chip 300. According to embodiments, the interposer substrate 150 may be arranged on a top surface of the first substrate 100. The interposer substrate 150 is formed based on silicon, and may electrically connect the chip stack structure 200 and the semiconductor chip 300 to each other. According to embodiments, the interposer substrate 150 may be electrically connected to the first substrate 100 through bumps. An under-fill material layer 180 surrounding the bumps may be arranged between the first substrate 100 and the interposer substrate 150. The under-fill material layer 180 may include, for example, epoxy resin formed in a capillary under-fill method. However, in some embodiments, a first molding member 290 may be directly filled in a gap between the first substrate 100 and the interposer substrate 150 through a molded under-fill process. In this case, the under-fill material layer 180 may be omitted.

In one or more examples, the interface 150 may include a wiring layer 140 and a body layer 130. The wiring layer 140 may be located on a top surface of the body layer 130. The wiring layer 140 may include a wiring pattern 121. The wiring pattern 121 may electrically connect the chip stack structure 200 and the semiconductor chip 300 to each other, or may electrically connect the chip stack structure 200 and the through electrode 157 to each other and the semiconductor chip 300 and the through electrode 131 to each other.

In one or more examples, the through electrode 131 may be formed inside the body layer 130. The through electrode 131 may penetrate the body layer 130 in the vertical direction Z. According to embodiments, the through electrode 131 may include a TSV. The through electrode 131 may be electrically connected to a bump through a pad formed on a bottom surface of the body layer 130.

Each of the chip stack structure 200 and the semiconductor chip 300 may be arranged on a top surface of the interposer substrate 150. Since the chip stack structure 200 is substantially the same as or similar to that described with reference to FIG. 1, a description thereof is omitted.

The semiconductor chip 300 may be arranged on the top surface of the interposer substrate 150 and spaced apart from the chip stack structure 200 in the first horizontal direction X. According to embodiments, the semiconductor chip 300 may include a logic chip. The logic chip may be, for example, a logic chip such as a CPU, a GPU, a microprocessor such as or an AP, an analog device, or a digital signal processor. However, the semiconductor chip 300 is not limited to a logic chip, and the semiconductor chip 300 may include a memory chip. The memory chip may be, for example, a volatile memory chip such as DRAM or SRAM, or may be a nonvolatile memory chip, such as PRAM, MRAM, FeRAM, or RRAM.

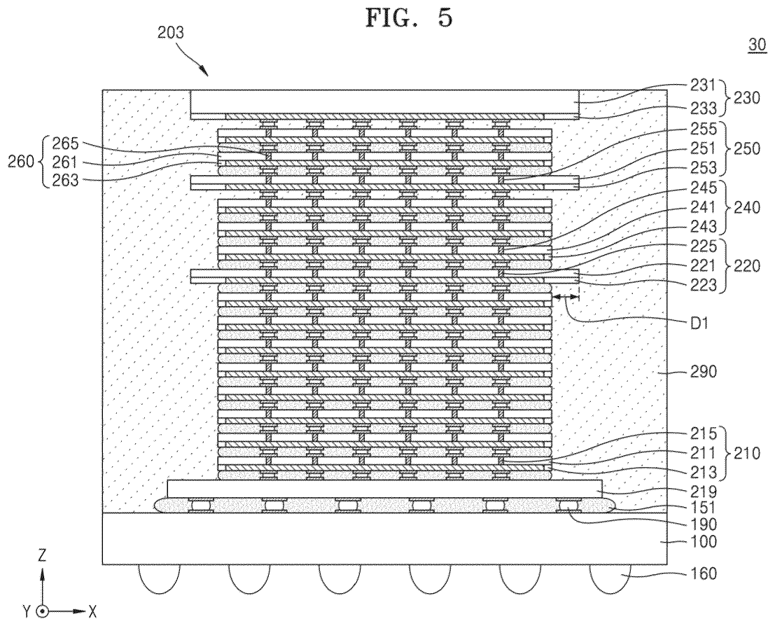

FIG. 5 is a cross-sectional view schematically illustrating a semiconductor package according to embodiments. Hereinafter, redundant descriptions between the semiconductor package 10 described with reference to FIG. 1 and a semiconductor package 30 to be described with reference to FIG. 5 are omitted and differences therebetween are mainly described.

Referring to FIG. 5, the semiconductor package 30 may include a first substrate 100, an external connection terminal 160, a chip stack structure 203, and a first molding member 290. According to embodiments, the chip stack structure 203 may include a base chip 219, a first semiconductor chip 210, a second semiconductor chip 220, a third semiconductor chip 240, a fourth semiconductor chip 250, a fifth semiconductor chip 260, and a top layer semiconductor chip 230.

According to embodiments, the base chip 219 may be a chip located lowermost in the chip stack structure 203. The first semiconductor chip 210 may be a chip positioned between the base chip 219 and the second semiconductor chip 220. When a plurality of first semiconductor chips 210 are provided, the first semiconductor chips 210 may be stacked and provided in the vertical direction Z. In this case, the first semiconductor chips 210 may be chips positioned between the base chip 219 and the second semiconductor chip 220. The second semiconductor chip 220 may be a chip located on the first semiconductor chip 210 located uppermost among the first semiconductor chips 210. A footprint of the second semiconductor chip 220 may be greater than a footprint of the first semiconductor chip 210. The third semiconductor chip 240 may be a chip positioned between the second semiconductor chip 220 and the fourth semiconductor chip 250. When a plurality of third semiconductor chips 240 are provided, the third semiconductor chips 240 may be stacked and provided in the vertical direction Z. In this case, the third semiconductor chips 240 may be chips positioned between the second semiconductor chip 220 and the fourth semiconductor chip 250. According to embodiments, the third semiconductor chip 240 may be substantially the same as the first semiconductor chip 210. In some embodiments, three third semiconductor chips 240 may be provided.

In one or more examples, the fourth semiconductor chip 250 may be arranged on the uppermost third semiconductor chip 240 among the third semiconductor chips 240. A footprint of the fourth semiconductor chip 250 may be greater than a footprint of the third semiconductor chip 240. In some embodiments, a footprint of the fourth semiconductor chip 250 may be substantially the same as a footprint of the second semiconductor chip 220.

The fifth semiconductor chip 260 may be a chip located on the fourth semiconductor chip 250. When a plurality of fifth semiconductor chips 260 are provided, the fifth semiconductor chips 260 may be stacked and provided in the vertical direction Z. In this case, the fifth semiconductor chips 260 may be chips positioned between the fourth semiconductor chip 250 and the top layer semiconductor chip 230. According to embodiments, the fifth semiconductor chip 260 may be substantially the same as the first semiconductor chip 210. In some embodiments, two fifth semiconductor chips 260 may be provided. The top layer semiconductor chip 230 may be located on the uppermost fifth semiconductor chip 260 among the plurality of fifth semiconductor chips 260.

In the semiconductor package 30 according to the embodiments of the present disclosure, the base chip 219 and the first semiconductor chips 210 may be first formed through a process, the second semiconductor chip 220 and the third semiconductor chips 240 may be formed through another process, to then be attached onto the first semiconductor chip 210 located uppermost among the plurality of the first semiconductor chips 210, and then the fourth semiconductor chip 250, the fifth semiconductor chips 260, and the top layer semiconductor chip 230 may be formed through another process to then be attached onto the fourth semiconductor chip 250. Accordingly, warpage of the chips in the semiconductor package 30 may be prevented.

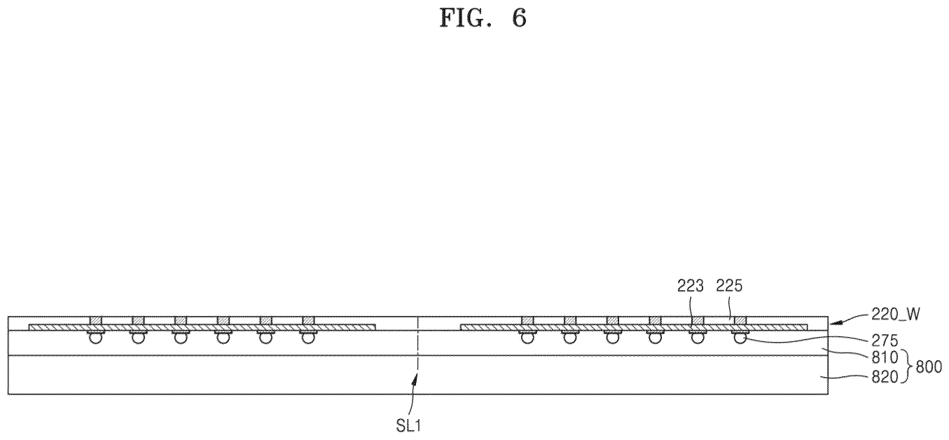

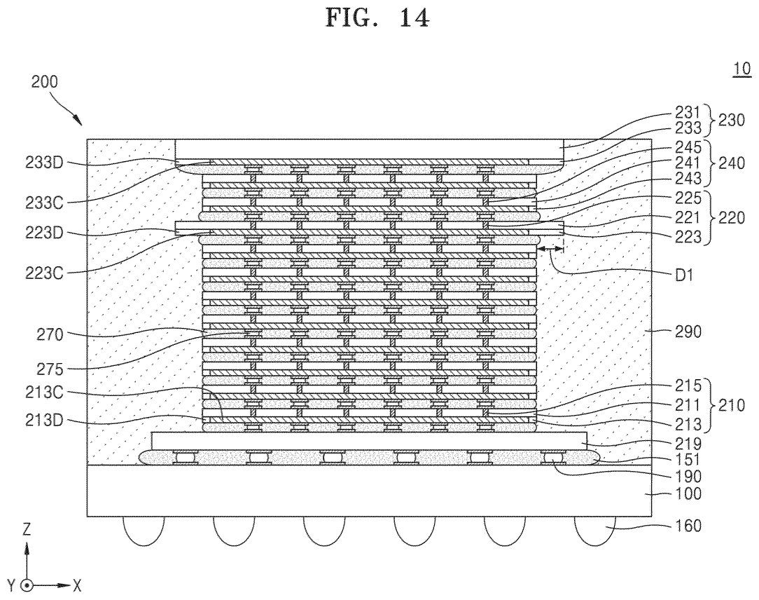

FIGS. 6 to 14 are cross-sectional views schematically illustrating a semiconductor package according to embodiments. Hereinafter, redundant descriptions of the semiconductor package 10 described with reference to FIG. 1 are omitted and differences are mainly described.

Referring to FIG. 6, a first base wafer 220_W is attached to a first carrier substrate 800. The first carrier substrate 800 may include a first support substrate 820 and a first glue layer 810. The first base wafer 220_W may be attached to the first carrier substrate 800 such that the second bump 275 faces the first carrier substrate 800. In some embodiments, the second bump 275 may be surrounded by the first glue layer 810. The first base wafer 220_W may include a second through electrode 225 and a second semiconductor device layer 223. The second semiconductor device layer 223 may not be formed near a first scribe lane SL1. For example, the second semiconductor device layer 223 may not be located in the first scribe lane SL1.

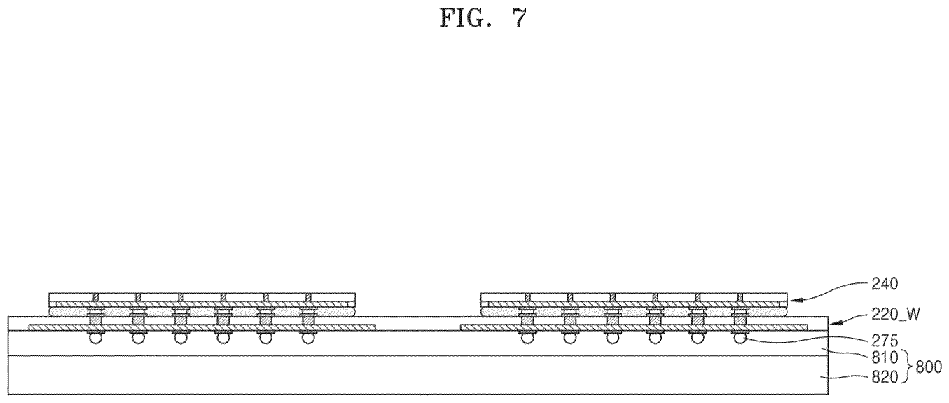

Referring to FIGS. 7 to 9, third semiconductor chips 240 are mounted on a top surface of the first base wafer 220_W. In this case, the third semiconductor chips 240 may be mounted to be stacked in the vertical direction Z. According to embodiments, two third semiconductor chips 240 may be stacked and mounted on the first base wafer 220_W in the vertical direction Z. The third semiconductor chips 240 may be formed from a semiconductor wafer including individual devices of different types formed through a process different from that of the first base wafer 220_W. A plurality of third semiconductor chips 240 mounted on the first base wafer 220_W are individual semiconductor chips cut from a wafer, and the plurality of third semiconductor chips 240 may be arranged on one first base wafer 220_W and spaced apart from each other in the horizontal directions X and Y. For example, as illustrated in FIG. 7, the plurality of third semiconductor chips 240 may be arranged on the first base wafer 220_W and spaced apart from each other in the horizontal directions X and Y.

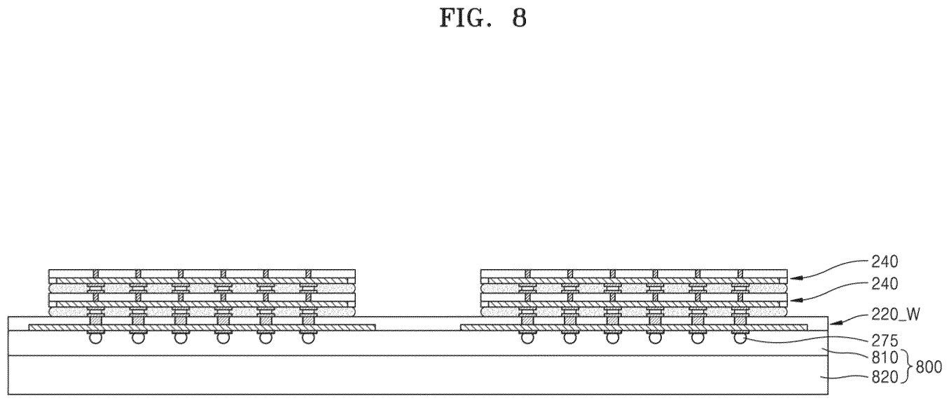

Then, as illustrated in FIG. 8, one or more additional third semiconductor chips 240 may be mounted on a top surface of each of the third semiconductor chips 240 arranged on the first base wafer 220_W. Therefore, the plurality of third semiconductor chips 240 may be provided in two layers on the first base wafer 220_W. However, the number of layers of the third semiconductor chips 240 to be stacked is not limited thereto, and the third semiconductor chips 240 may be stacked in three or more layers.

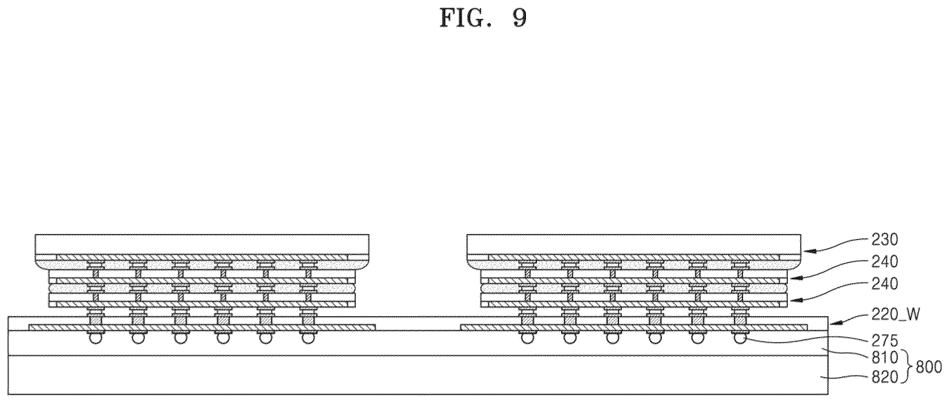

Then, as shown in FIG. 9, the top layer semiconductor chip 230 is mounted on a top surface of the third semiconductor chip 240 located uppermost among the third semiconductor chips 240. The top layer semiconductor chip 230 may be formed from a semiconductor wafer including a different type of individual devices formed through a process from a process of a wafer on which the third semiconductor chips 240 are formed.

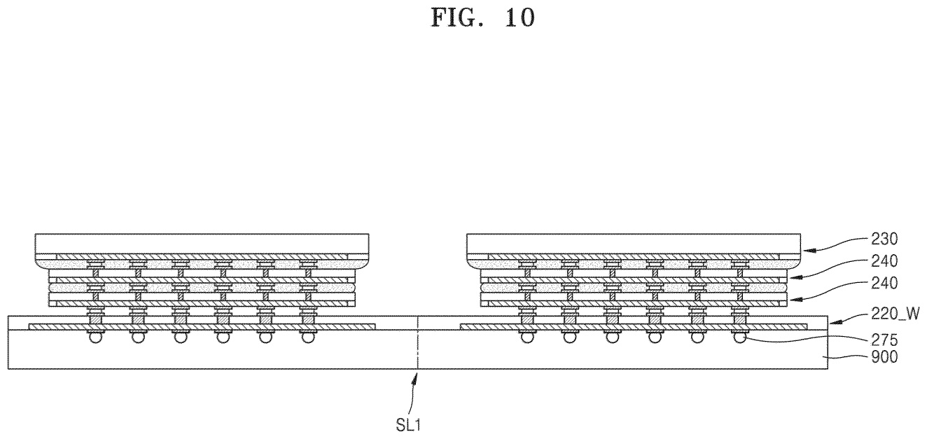

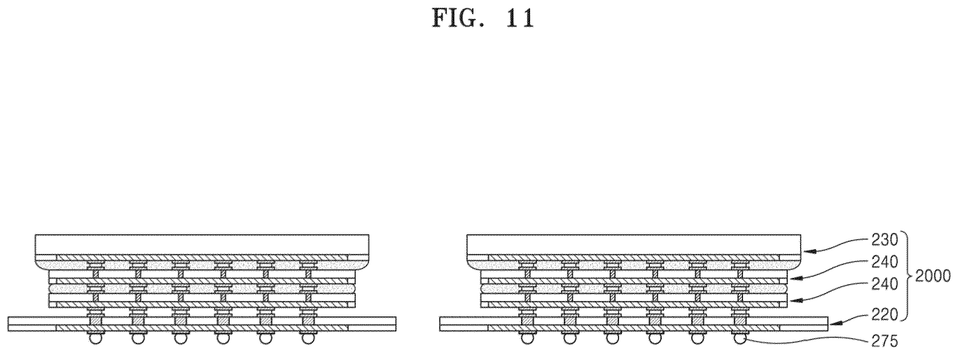

Referring to FIGS. 10 and 11, the first carrier substrate 800 is removed, the first base wafer 220_W and the chips stacked on the first base wafer 220_W are moved onto a top surface of a dicing tape 900, and the first base wafer 220_W is cut along a first scribe lane SL1 to form a plurality of second structures 2000. Each of the plurality of second structures 2000 may include a second semiconductor chip 220, a plurality of third semiconductor chips 240, and a top layer semiconductor chip 230.

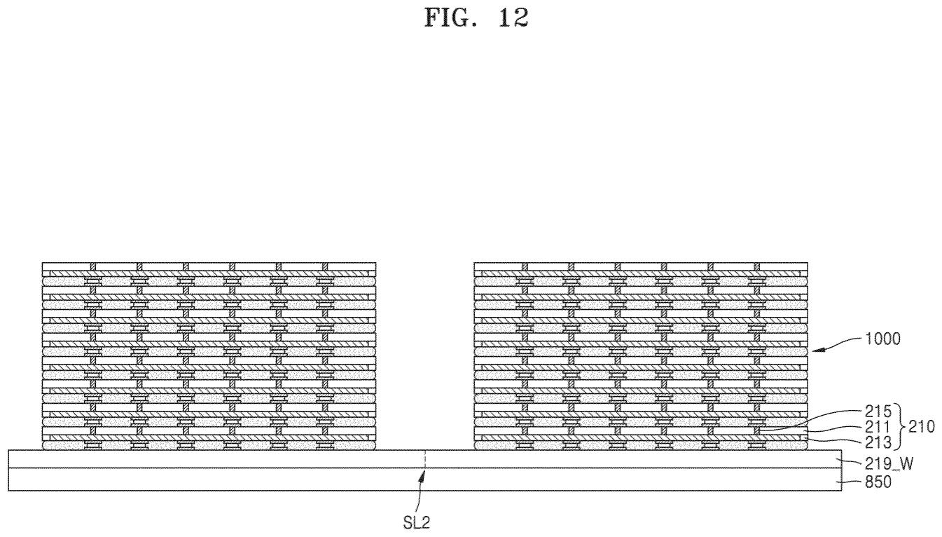

Referring to FIGS. 12 to 14, a second base wafer 219_W and a plurality of first structures 1000 mounted on the second base wafer 219_W are provided on a second carrier substrate 850. Each of the plurality of first structures 1000 may include first semiconductor chips 210. The plurality of first structures 1000 may be arranged to be spaced apart from each other in the horizontal directions X and Y. A second scribe lane SL2, which is an area in which individual devices are not formed, may be formed on the second base wafer 219_W. Thereafter, the second structure 2000 is mounted on the top surface of each of the plurality of first structures 1000. Thereafter, a first molding member 290 surrounding the first structures 1000 and the second structures 2000 is formed on the second base wafer 219_W, and then the second base wafer 219_W and the first molding member 290 are cut along the second scribe lane SL2 to provide an individual semiconductor package 10.

While the embodiments of the present disclosure have been particularly shown and described with reference to embodiments thereof, it will be understood that various changes in form and details may be made therein without departing from the spirit and scope of the following claims.

What is claimed is:

1. A semiconductor package comprising:
a first substrate;
a base chip on the first substrate;
a plurality of first semiconductor chips stacked, in a first direction, on the base chip;
a second semiconductor chip stacked, in the first direction, on an uppermost first semiconductor chip among the plurality of first semiconductor chips;
a plurality of third semiconductor chips stacked, in the first direction, on the second semiconductor chip; and
a fourth semiconductor chip stacked, in the first direction, on an uppermost third semiconductor chip among the plurality of third semiconductor chips,
wherein a footprint of the second semiconductor chip is greater than a footprint of each of the first semiconductor chips and each of the third semiconductor chips, and
wherein a footprint of the base chip is greater than a footprint of the second semiconductor chip.

2. The semiconductor package of claim 1, wherein an adhesive layer is provided between the uppermost first semiconductor chip among the plurality of first semiconductor chips and the second semiconductor chip.

3. The semiconductor package of claim 1, wherein a bump and a first molding member surrounding the bump are provided between the uppermost first semiconductor chip among the plurality of first semiconductor chips and the second semiconductor chip.

4. The semiconductor package of claim 1, wherein a chip pad and a first molding member surrounding the chip pad are provided between the uppermost first semiconductor chip among the plurality of first semiconductor chips and the second semiconductor chip without a bump therebetween.

5. The semiconductor package of claim 1, wherein a number of the first semiconductor chips is eight, and a number of the third semiconductor chips is two.

6. The semiconductor package of claim 1, wherein a distance between a side surface of the first semiconductor chip in a second direction perpendicular to the first direction and a side surface of the second semiconductor chip in the second direction is in a range of about 50 μm to about 100 μm.

7. The semiconductor package of claim 1, wherein an interposer substrate is on the first substrate, and a base chip and a semiconductor chip spaced apart from the base chip in a second direction perpendicular to the first direction are on the interposer substrate, wherein
wherein the interposer substrate comprises a body layer, a wiring layer, and a through electrode penetrating the body layer in the first direction.

8. The semiconductor package of claim 1, wherein a first adhesive layer is provided between each first semiconductor chip adjacent to each other among the first semiconductor chips,
wherein a second adhesive layer is provided between the uppermost first semiconductor chip among the first semiconductor chips and the second semiconductor chip, and
wherein a footprint of the second adhesive layer is greater than a footprint of the first adhesive layer.

9. The semiconductor package of claim 1, wherein each of the first semiconductor chips comprises a first core region in which individual devices are formed, and a first dummy region surrounding the first core region in which individual devices are not formed, and
wherein the second semiconductor chip comprises a second core region in which individual devices are formed, and a second dummy region surrounding the second core region in which individual devices are not formed.

10. The semiconductor package of claim 9, wherein a footprint of the first core region is substantially the same as a footprint of the second core region.

11. The semiconductor package of claim 1, wherein a thickness of the fourth semiconductor chip in is in a range of about 140 μm to about 180 μm.

12. A semiconductor package comprising:
a first substrate;
a base chip on the first substrate;
a plurality of first semiconductor chips stacked, in a first direction, on the base chip;
a second semiconductor chip stacked, in the first direction, on an uppermost first semiconductor chip among the plurality of first semiconductor chips;
a plurality of third semiconductor chips stacked, in the first direction, on the second semiconductor chip;
a fourth semiconductor chip stacked, in the first direction, on an uppermost third semiconductor chip among the plurality of third semiconductor chips;
a plurality of fifth semiconductor chips stacked, in the first direction, on the fourth semiconductor chip; and
a sixth semiconductor chip stacked, in the first direction, on an uppermost fifth semiconductor chip among the plurality of fifth semiconductor chips, wherein
a footprint of each of the second semiconductor chip and the fourth semiconductor chip is greater than a footprint of each of the first semiconductor chips, each of the third semiconductor chips, and each of the fifth semiconductor chips, and
a footprint of the base chip is greater than a footprint of each of the second semiconductor chips and the fourth semiconductor chip.

13. The semiconductor package of claim 12, wherein an interposer substrate is on the first substrate, and a base chip and a semiconductor chip spaced apart from the base chip in a second direction perpendicular to the first direction are on the interposer substrate,
wherein the interposer substrate comprises a body layer, a wiring layer, and a through electrode penetrating the body layer in the first direction, and
wherein a wiring pattern electrically connecting the base chip to the semiconductor chip is included inside the wiring layer.

14. The semiconductor package of claim 12, wherein a thickness of the sixth semiconductor chip in the first direction is in a range of about 140 μm to about 180 μm, and
wherein a distance between a side surface of the first semiconductor chip in a second direction perpendicular to the first direction and a side surface of the second semiconductor chip in the second direction is in a range of about 50 μm to about 100 μm.

15. The semiconductor package of claim 12, wherein an adhesive layer is provided between the uppermost first semiconductor chip among the plurality of first semiconductor chips and the second semiconductor chip.

16. The semiconductor package of claim 12, wherein a chip pad and a first molding member surrounding the chip pad are provided between the uppermost first semiconductor chip among the plurality of first semiconductor chips and the second semiconductor chip, without a bump therebetween.

17. The semiconductor package of claim 12, wherein a bump and a first molding member surrounding the bump are provided between the uppermost first semiconductor chip among the plurality of first semiconductor chips and the second semiconductor chip, and between an uppermost third semiconductor chip among the plurality of third semiconductor chips and the fourth semiconductor chip.

18. A semiconductor package comprising:
a first substrate;
a base chip on the first substrate;
a plurality of first semiconductor chips stacked, in a first direction, on the base chip and having a footprint smaller than a footprint of the base chip;
a second semiconductor chip stacked, in the first direction, on an uppermost first semiconductor chip among the plurality of first semiconductor chips and having a footprint larger than a footprint of each of the first semiconductor chips;
a plurality of third semiconductor chips stacked, in the first direction, on the second semiconductor chip and having a footprint smaller than the footprint of the second semiconductor chip; and
a fourth semiconductor chip stacked, in the first direction, on an uppermost third semiconductor chip among the plurality of third semiconductor chips, wherein
the number of the first semiconductor chips is eight, the number of the third semiconductor chips is two,
a first adhesive layer is provided between each first semiconductor chip adjacent to each other in the first direction among the first semiconductor chips, a second adhesive layer is provided between an uppermost first semiconductor chip among the first semiconductor chips and the second semiconductor chip, a footprint of the second adhesive layer is greater than a footprint of the first adhesive layer, and
a distance between a side surface of the first semiconductor chip in a second direction perpendicular to the first direction and a side surface of the second semiconductor chip in the second direction is in a range of about 50 μm to about 100 μm.

19. The semiconductor package of claim 18, wherein an interposer substrate is on the first substrate, and a base chip and a semiconductor chip spaced apart from the base chip in the second direction are on the interposer substrate, wherein
wherein the interposer substrate comprises a body layer, a wiring layer, and a through electrode penetrating the body layer in the first direction, and
wherein a wiring pattern electrically connecting the base chip to the semiconductor chip is included inside the wiring layer.

20. The semiconductor package of claim 18, wherein each of the first semiconductor chips comprises a first core region in which individual devices are formed, and a first dummy region surrounding the first core region and in which individual devices are not formed, and the second semiconductor chip comprises a second core region in which individual devices are formed, and a second dummy region surrounding the second core region and in which individual devices are not formed, wherein the first core region and the second core region have substantially the same footprint.
